(19) United States
(12) Patent Application Publication
(10) Pub. No.: US 2021/0366755 A1
(43) Pub. Date: Nov. 25, 2021

(54) MASS TRANSFER DEVICE AND TRANSFER METHOD THEREFOR

(71) Applicant: CHONGQING KONKA PHOTOELECTRIC TECHNOLOGY RESEARCH INSTITUTE CO., LTD., Chongqing (CN)

(72) Inventor: Chen HUNG-WEN, Chongqing (CN)

(21) Appl. No.: 17/360,661

(22) Filed: Jun. 28, 2021

Related U.S. Application Data
(63) Continuation of application No. PCT/CN2020/092424, filed on May 26, 2020.

(30) Foreign Application Priority Data
May 22, 2020 (CN) 202010443851.9

(51) Int. Cl. H01L 21/68; H01L 33/48; H01L 25/075; H01L 27/15

(52) U.S. Cl. CPC H01L 21/68; H01L 27/156; H01L 25/0753; H01L 33/48

(57) ABSTRACT

A mass transfer device and a transfer method therefor are provided. The mass transfer device includes a transfer container. The transfer container is filled with insulating liquid and provided with two electrode plates. The two electrode plates are arranged opposite to each other and have opposite electrical polarities. One of the two electrode plates is provided with a second substrate on a surface of the electrode plate opposite to the other one of the two electrode plates. The second substrate is configured to hold transferred light-emitting diode (LED) chips. The transfer container is externally provided with a laser emitter. The laser emitter is aligned with LED chips on a first substrate. The first substrate is arranged between the two electrode plates and mounted on a first displacement device. The first displacement device is configured to control the first substrate to move vertically downward.

### CROSS-REFERENCE TO RELATED APPLICATION(S)

This application is a continuation of International Application No. PCT/CN2020/092424, filed on May 26, 2020, which claims priority to Chinese Patent Application No. 202010443851.9, filed on May 22, 2020, the disclosures of which are hereby incorporated by reference in their entireties.

### TECHNICAL FIELD

This disclosure relates to the technical field of mass transfer, and particularly to a mass transfer device and a mass transfer method therefor.

### BACKGROUND

With the development of science and technology, a light-emitting diode (LED) has become an important display element for a display screen because of its advantages such as high stability, long lifetime, low power consumption, good color saturation, fast response speed, and strong contrast. The existing LED panel is generally equipped with a large number of LED chips. During manufacturing of a display screen, it is necessary to transfer LED chips to a display backplane of the display screen from a growth substrate of the LED chips.

At present, when LED chips need to be transferred to a display backplane from a growth substrate of the LED chips, it is generally necessary to pick up LED chips on a first substrate by means of a transfer head and then place the picked-up LED chips on a second substrate. However, the above-mentioned method is often limited by the size of the transfer head. With the further development of LED display technology, the size of LED chips has become increasingly smaller, and the size of the existing micro LED has even reached the μm level. Because the size of the micro LED chip is too small, it is difficult for the transfer head to pick it up. Therefore, the above-mentioned transfer method can no longer meet requirements of transferring of micro LED chips well.

### SUMMARY

A mass transfer device is provided. The mass transfer device includes a transfer container. The transfer container is filled with insulating liquid and provided with two electrode plates. The two electrode plates are arranged opposite to each other and have opposite electrical polarities. One of the two electrode plates is vertically provided with a second substrate on a surface of the electrode plate opposite to the other one of the two electrode plates. The second substrate is configured to hold transferred light-emitting diode (LED) chips. The transfer container is externally provided with a laser emitter. The laser emitter is aligned with LED chips on a first substrate. The first substrate is vertically arranged between the two electrode plates. The first substrate is mounted on a first displacement device. The first displacement device is configured to control the first substrate to move vertically downward at a preset speed.

A mass transfer method is further provided. The mass transfer method includes the following. Apply charges to all LED chips on a first substrate. Two electrode plates in a transfer container are energized to form a directional electric field between the two electrode plates, where the first substrate is vertically arranged between the two electrode plates, the two electrode plates are arranged opposite to each other and have opposite electrical polarities, and one of the two electrode plates is vertically provided with a second substrate on a surface of the electrode plate opposite to the other one of the two electrode plates. After applying the charges, the first substrate is moved to a predetermined position between the two electrode plates. Laser irradiation is performed to make LED chips to-be-transferred be detached from the first substrate and move directionally in insulating liquid in the transfer container to a predetermined position of the second substrate under action of the electric field.

### BRIEF DESCRIPTION OF THE DRAWINGS

For ease of description, the disclosure will be described in detail with reference to illustrative implementations and accompanying drawings.

FIG. 1 is a schematic diagram illustrating a cross-sectional structure of a mass transfer device according to implementations.

FIG. 2 is a schematic diagram illustrating a cross-sectional structure of a mass transfer device according to other implementations.

FIG. 3 is a schematic diagram illustrating a top-view structure of a mass transfer device according to other implementations.

FIG. 4 is a schematic flowchart illustrating a mass transfer method according to implementations.

FIG. 5 is a schematic flowchart illustrating a mass transfer method according to other implementations.

FIG. 6 is a schematic flowchart illustrating a mass transfer method according to other implementations.

### DETAILED DESCRIPTION

In order to make objectives, technical solutions, and advantages of the disclosure more clear and definite, the disclosure will be described in detail below with reference to accompanying drawings and illustrative implementations. It should be understood that, the implementations described below are merely used to explain the disclosure, and should not be construed as limiting the disclosure.

It should be understood that in the description of the disclosure, an orientation or a positional relationship indicated by the terms “center”, “vertical”, “horizontal”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, etc. are based on an orientation or a positional relationship illustrated in the accompanying drawings, which is only for simplifying and facilitating description of the disclosure, rather than indicating or implying that a device or a component must have a specific orientation, be constructed and operated in a specific orientation, and therefore should not be understood as a limitation to the disclosure. In addition, the terms “first”, “second”, and the like are only used for descriptive purposes, which should not be understood as indicating or implying relative importance or implicitly indicating the number of technical features referred to herein. Therefore, features restricted by terms “first”, “second”, and the like can explicitly or implicitly include at least one of the features. In the context of the disclosure, unless stated otherwise, “multiple” refers to “at least two”, such as two, three, and the like.

In the disclosure, terms “installing”, “coupling”, “connecting”, and the like referred to herein should be understood in broader sense, unless stated otherwise. For example, coupling may be a fixed coupling, a removable coupling, or an integrated coupling, may be a mechanical coupling, an electrical coupling, and may be a direct coupling, an indirect coupling through a medium, or a communication coupling between two components or an interaction coupling between two components. For those of ordinary skill in the art, the above terms in the present disclosure can be understood according to specific situations.

In view of the above deficiencies, implementations of the disclosure provide a mass transfer device and a mass transfer method which are suitable for small-sized micro LED chips.

A mass transfer device is provided. The mass transfer device includes a transfer container. The transfer container is filled with insulating liquid and provided with two electrode plates. The two electrode plates are arranged opposite to each other and have opposite electrical polarities. One of the two electrode plates is vertically provided with a second substrate on a surface of the electrode plate opposite to the other one of the two electrode plates. The second substrate is configured to hold transferred light-emitting diode (LED) chips. The transfer container is externally provided with a laser emitter. The laser emitter is aligned with LED chips on a first substrate. The first substrate is vertically arranged between the two electrode plates. The first substrate is mounted on a first displacement device. The first displacement device is configured to control the first substrate to move vertically downward at a preset speed.

According to the mass transfer device of the disclosure, since the directional electric field is provided in the mass transfer device, the LED chips on the first substrate after applying charges can move directionally under action of an electric force after being detached from the first substrate. In this way, the LED chips can be transferred to the second substrate. For the mass transfer device of the disclosure, no transfer head is required, and so a transfer process is not limited by the size of the micro LED chip, which greatly meets requirements of transferring of micro LED chips of various sizes.

In some implementations, the second substrate is mounted on a second displacement device. The second displacement device is configured to control the second substrate to move vertically upward at a preset speed.

In some implementations, the laser emitter is arranged above the liquid surface of the insulating liquid.

In some implementations, the laser emitter is embodied as three laser emitters. The number of the laser emitters is consistent with that of the first substrates.

In some implementations, each of the laser emitters is mounted on a mounting position of a laser-emitter fixing frame. Adjacent mounting positions are separated by a space for placing the first substrate.

In some implementations, the laser-emitter fixing frame is provided with a regulator. The regulator is configured to adjust a distance between two adjacent mounting positions.

In some implementations, the second substrate has openings for holding transferred LED chips. The number of the openings is greater than three.

In some implementations, each of the openings is coated with an adhesive layer.

In some implementations, three first substrates are provided with red LED chips, green LED chips, and blue LED chips respectively.

In some implementations, the mass transfer device further includes a charge generator. The charge generator is configured to apply charges to LED chips on the first substrates.

In some implementations, the mass transfer device further includes a power controller connected with the two electrode plates. The power controller is configured to adjust an electric field intensity between the two electrode plates.

In some implementations, the first substrate is provided with a distance control component. The distance control component is configured to adjust a distance between the first substrate and the second substrate.

In some implementations, the insulating liquid is insulating oil.

Based on a same inventive concept, a mass transfer method is further provided. The mass transfer method includes the following. Apply charges to all LED chips on a first substrate. Two electrode plates in a transfer container are energized to form a directional electric field between the two electrode plates, where the first substrate is vertically arranged between the two electrode plates, the two electrode plates are arranged opposite to each other and have opposite electrical polarities, and one of the two electrode plates is vertically provided with a second substrate on a surface of the electrode plate opposite to the other one of the two electrode plates. After applying the charges, the first substrate is moved to a predetermined position between the two electrode plates. Laser irradiation is performed to make LED chips to-be-transferred be detached from the first substrate and move directionally in insulating liquid in the transfer container to a predetermined position of the second substrate under action of the electric field.

According to the mass transfer method of the disclosure, charges are applied to the LED chips on the first substrate. Since the directional electric field is provided in the mass transfer device, after the LED chips are detached from the first substrate, the LED chips can move directionally under action of an electric force generated by the mass transfer device. In this way, the LED chips can be transferred to the second substrate. During a transfer process, there is no need to pick up LED chips by means of a transfer head, and so the transfer process is not limited by the size of the micro LED chip, which greatly meets requirements of transferring of micro LED chips of various sizes.

In some implementations, the first substrate is moved to the predetermined position between the two electrode plates after applying the charges as follows. The first substrate is moved to a position between the two electrode plates after applying the charges. The LED chips to-be-transferred are immersed in the insulating liquid, where a center of gravity of the LED chip and the liquid surface of the insulating liquid are on a same horizontal plane.

In some implementations, the first substrate is embodied as three first substrates. The first substrate is moved to the predetermined position between the two electrode plates after applying the charges as follows. The three first substrates are moved to respective predetermined positions between the two electrode plates after applying the charges.

In some implementations, the mass transfer method further includes the following. After moving the first substrate to the predetermined position between the two electrode plates after applying the charges, stop moving the first substrate.

In some implementations, the mass transfer method further includes the following. After moving directionally in the insulating liquid in the transfer container to the predetermined position of the second substrate under action of the electric field, the distance between the first substrate and the second substrate is adjusted to a preset value, and the first substrate is moved to a predetermined position between the two electrode plates at a preset speed.

In some implementations, the mass transfer method further includes the following. After moving directionally in the insulating liquid in the transfer container to the predetermined position of the second substrate under action of the electric field, the electric field between the two electrode plates is adjusted to a preset value, and the first substrate is moved to a predetermined position between the two electrode plates at a preset speed.

In some implementations, applying charges to all LED chips on the first substrate is as follows. Apply different amounts of charges to different LED chips on the first substrates.

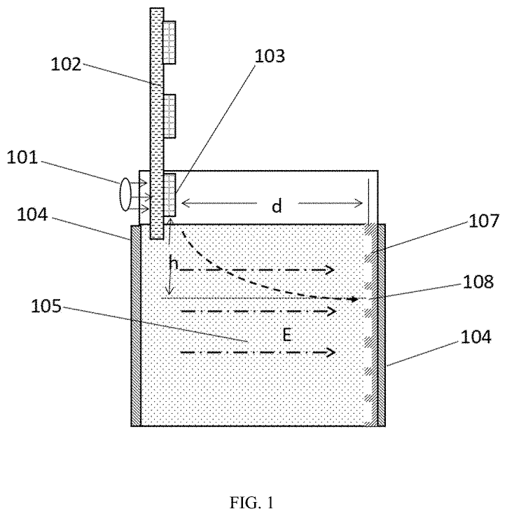

A mass transfer device of the disclosure will be described in detail below with reference to implementations. As illustrated in FIG. 1, the mass transfer device includes a transfer container. The transfer container is externally provided with a laser emitter 101. The laser emitter 101 is aligned with LED chips 103 on a first substrate 102. The LED chip 103 on the first substrate 102 carries a predetermined amount of charges, where the LED chip 103 may be positively or negatively charged. The first substrate 102 is arranged between two electrode plates 104 in the transfer container. The first substrate 102 is mounted on a first displacement device (not illustrated). The first displacement device is configured to control the first substrate 102 to move vertically downward at a preset speed. The transfer container is filled with insulating liquid 105. The insulating liquid 105 may be insulating oil, and the insulating oil is prepared by adding an antioxidant to a deeply refined lubricating oil base oil. In implementations of the disclosure, the insulating liquid has characteristics of insulation and low viscosity, which allows the LED chip 103 entering the insulating liquid to move in the insulating liquid. The laser emitter 101 is mounted on a mounting position of a laser-emitter fixing frame 106. The laser emitter 101 is arranged above the liquid surface of the insulating liquid 105. The transfer container is provided with two electrode plates 104 arranged opposite to each other. The two electrodes plates104 are both immersed in the insulating oil and disposed at two opposite sides of the transfer container respectively. The two electrode plates104 have opposite electrical polarities, so a stable electric field is generated between the two electrode plates104. In implementations of the disclosure, when LED chips 103 to-be-transferred contact the liquid surface of the insulating oil, the laser emitter 101 emits laser lights to irradiate the LED chips 103 on the first substrate 102, so that the LED chips 103 are detached from the first substrate 102 and enter in the insulating oil. Since charges are applied to the LED chips 103, after entering the insulating oil, the LED chip 103 is subjected to a directional electric force (also known as electric field force) generated by the two electrode plates 104, where the electric force is greater than the resistance of the insulating oil to the LED chip 103, and the gravity of the LED chip 103 is also greater than the buoyancy (i.e., buoyant force) of the insulating oil to the LED chip 103. Therefore, under action of both the electric force and the gravity, the LED chip 103 will move in an arc path in the transfer container. One of the electrode plates 104 is provided with a second substrate 107 on a surface of the electrode plate opposite to the other one of the two electrode plates 104. The second substrate 107 has openings108 for holding transferred LED chips 103. Therefore, the LED chip 103 will eventually move to the opening 108 of the second substrate 107. The opening 108 of the second substrate 107 is coated with an adhesive layer, and therefore, the LED chip 103 will be bonded and fixed in the second substrate 107. In this case, one round of transfer is completed.

Since the second substrate 107 has multiple openings 108 and each of the openings 108 is used for holding one LED chip 103, after a group of LED chips 103 on the first substrate 102 are transferred to the second substrate 107, the first substrate 102 is moved downward to make another group of LED chips 103 that have not been immersed in the insulating oil be immersed in the insulating oil, and then the group of LED chips 103 immersed are transferred. The aforementioned operations are repeatedly performed until each opening 108 on the second substrate 107 is filled with the LED chip 103. In this case, one round of transfer is completed, and accordingly, the second substrate 107 is taken out of the transfer container and another second substrate 107 is put in the transfer container to continue transferring of LED chips 103 to the newly put second substrate 107.

In some implementations, the mass transfer device further includes a second displacement device (not illustrated). The second substrate 107 is mounted on the second displacement device. The second displacement device is configured to control the second substrate to move vertically upward at a preset speed. After a group of LED chips 103 on the first substrate 102 are transferred to the second substrate 107, the first substrate 102 is moved downward to make another group of LED chips 103 that have not been immersed in the insulating oil be immersed in the insulating oil, and then the group of LED chips 103 immersed are transferred. At the same time, the second substrate is controlled to move vertically upward at a preset speed. In this way, each LED chip 103 transferred can reach an appropriate opening 108 of the second substrate 107.

In some implementations, the mass transfer device further includes a charge generator. The charge generator is configured to apply charges to LED chips 103 on the first substrate 102.

In some implementations, the mass transfer device further includes a power controller. The power controller is connected with the two electrode plates 104. The power controller is configured to adjust an electric field intensity between the two electrode plates 104. After one round of transfer is completed, the electric field intensity may be adjusted, so as to adjust a position where the LED chip 103 reaches the second substrate 107 in the next round.

In some implementations, the first substrate 102 is provided with a distance control component. The distance control component is configured to adjust a distance between the first substrate 102 and the second substrate 107. After one round of transfer is completed, the distance between the two substrates may be adjusted, so as to adjust a position where the LED chip 103 reaches the second substrate 107 in the next round.

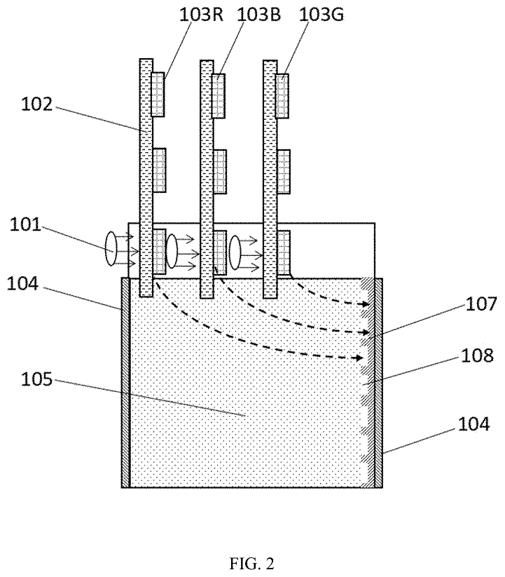

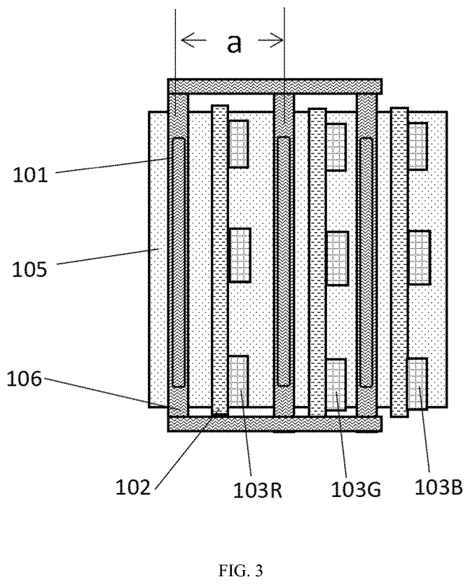

The mass transfer device of the disclosure may be used to transfer one type of LED chips 103, and may also be used to transfer multiple types of different LED chips 103 at the same time. A mass transfer device of the disclosure for transferring multiple types of different LED chips 103 will be described in detail below with reference to other implementations. As illustrated in FIG. 2 and FIG. 3, the mass transfer device includes a transfer container. The transfer container is externally provided with a laser-emitter fixing frame 106. The laser-emitter fixing frame 106 has three mounting positions. Each mounting position is equipped with a laser emitter 101. The laser-emitter fixing frame 106 is further provided with a regulator. The regulator is configured to adjust a distance between two adjacent mounting positions. Adjacent mounting positions are separated by a space for placing a first substrate 102. In some implementations, the first substrate 102 is embodied as three first substrates 102. Each first substrate 102 is provided with LED chips 103 of one color. The three first substrates 102 are all placed in a vertical space between two electrode plates 104 in the transfer container. LED chips 103 on the three first substrates 102 are red LED chips, green LED chips, and blue LED chips respectively (i.e., one first substrate is provided with red LED chips, another first substrate is provided with green LED chips, and the other first substrate is provided with blue LED chips). One laser emitter 101 is aligned with LED chips 103 on one first substrate 102. The LED chip 103 on the first substrate 102 carries a predetermined amount of charges. The amount of charges carried by the red LED chip, the amount of charges carried by the green LED chip, and the amount of charges carried by the blue LED chip are different. The LED chip 103 may be positively or negatively charged. The transfer container is filled with insulating liquid 105. The insulating liquid105 may be insulating oil, and the insulating oil is prepared by adding an antioxidant to a highly refined lubricating oil base oil. In implementations of the disclosure, the insulating liquid has characteristics of insulation and low viscosity, which allows the LED chip 103 entering the insulating liquid to move in insulating liquid.

The laser emitter 101 is arranged above the liquid surface of the insulating liquid 105. The transfer container is provided with two electrode plates 104 arranged opposite to each other. The two electrode plates 104 are both immersed in the insulating oil and disposed at two opposite sides of the transfer container respectively. The two electrode plates 104 have opposite electrical polarities, so a stable electric field is generated between the two electrode plates 104. In implementations of the disclosure, the amount of charges carried by the red LED chip, the amount of charges carried by the green LED chip, and the amount of charges carried by the blue LED chip are not the same. When LED chips 103 to-be-transferred contact the liquid surface of the insulating oil, each of three laser emitters 101 irradiates LED chips 103 on the first substrate 102 corresponding to the laser emitter 101, to make red LED chips 103R, green LED chips 103G, and blue LED chips 103B be detached from the (three) first substrates 102 and enter the insulating oil. After entering the insulating oil, the LED chip 103 is subjected to a directional electric force generated by the two electrode plates 104, where the electric force is greater than the resistance of the insulating oil to the LED chip 103, and the gravity of the LED chip 103 is also greater than the buoyancy of the insulating oil to the LED chip 103. Therefore, under action of both the electric force and the gravity, the LED chip 103 will move in an arc path in the transfer container. Since the amount of charges carried by the red LED chip, the amount of charges carried by the green LED chip, and the amount of charges carried by the blue LED chip are different, motion trajectories of three types of LED chips 103 are different. One of the electrode plates 104 is provided with a second substrate 107 on a surface of the electrode plate opposite to the other one of the two electrode plates 104. The second substrate 107 has openings 108 for holding transferred LED chips 103, where the number of the openings 108 is greater than three. Therefore, three types of LED chips 103 will eventually move to different openings 108 of the second substrate 107. The opening 108 of the second substrate 107 is coated with an adhesive layer, and therefore, the LED chip 103 will be bonded and fixed in the second substrate 107. In this case, one round of transfer is completed.

Since the second substrate 107 has multiple openings 108 and each of the openings 108 is used for holding one LED chip 103, after a group of LED chips 103 on the first substrate 102 are transferred to the second substrate 107, the first substrate 102 is moved downward to make another group of LED chips 103 that have not been immersed in the insulating oil be immersed in the insulating oil, and then the group of LED chips 103 immersed are transferred. The aforementioned operations are repeatedly performed until each opening 108 on the second substrate 107 is filled with the LED chip 103. In this case, one round of transfer is completed, and accordingly, the second substrate 107 is taken out of the transfer container and another second substrate 107 is put in the transfer container to continue transferring of LED chips 103 to the newly put second substrate 107.

In some implementations, the mass transfer device further includes a charge generator. The charge generator is configured to apply charges to LED chips 103 on the first substrate 102.

In some implementations, the mass transfer device further includes a power controller. The power controller is connected with the two electrode plates 104. The power controller is configured to adjust an electric field intensity between the two electrode plates 104. After one round of transfer is completed, the electric field intensity may be adjusted, so as to adjust a position where the LED chip 103 reaches the second substrate 107 in the next round.

In some implementations, the first substrate 102 is provided with a distance control component. The distance control component is configured to adjust a distance between the first substrate 102 and the second substrate 107. After one round of transfer is completed, the distance between the two substrates may be adjusted, so as to adjust a position where the LED chip 103 reaches the second substrate 107 in the next round.

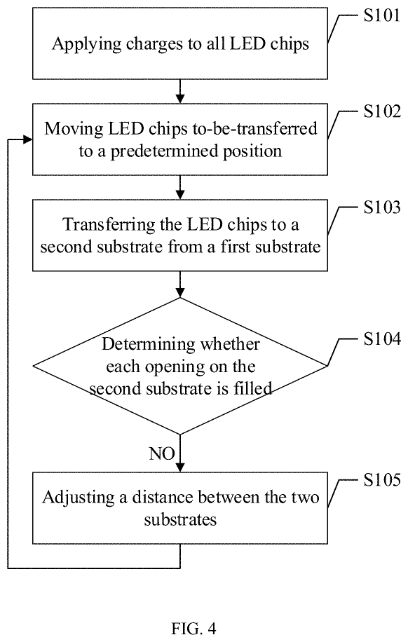

A mass transfer method of the disclosure will be described in detail below with reference to implementations. As illustrated in FIG. 4, the mass transfer method includes the following.

At block S101, apply charges to all LED chips.

The surfaces of all the LED chips on a first substrate are positively or negatively charged by frictional charging, induction charging, contact charging, or other methods, and the amount of charges is q. In the implementation, the surface of the LED chip is positively charged. Two electrode plates in a transfer container are energized to form a directional electric field E between the two electrode plates. In the implementation, the electrode plate on the left is a positive electrode and the electrode plate on the right is a negative electrode. Therefore, the electric field is in a rightward direction.

At block S102, LED chips to-be-transferred are moved to a predetermined position.

After applying the charges, the first substrate is moved to a predetermined position between the two electrode plates. In some implementations, after applying the charges, the first substrate is moved to a position between the two electrode plates. The LED chips to-be-transferred are immersed in insulating liquid, where a center of gravity of the LED chip and the liquid surface of the insulating liquid are on a same horizontal plane. When the LED chips are moved to the predetermined position, stop moving the first substrate. Since the movement of the first substrate stops, an initial velocity of the LED chip entering the insulating liquid is 0, which is convenient for calculating a falling distance h of the LED chip.

In some implementations, the movement of the first substrate does not stop. In this case, it is necessary to obtain the initial velocity V₀ of the LED chip entering the insulating liquid when calculating the falling distance h.

At block S103, the LED chips are transferred to a second substrate from the first substrate.

The LED chips to-be-transferred are detached from the first substrate by laser irradiation. The LED chips move directionally in the insulating liquid in the transfer container to a predetermined position of the second substrate under action of the electric field. After entering the insulating liquid, because charges are applied to the surface of the LED chip, under action of the electric field E, the LED chip is subjected to a force in a same direction as the electric field, where the force is required to be greater than the resistance f of the insulating liquid to the LED chip, and the buoyancy F of the selected insulating liquid to the LED chip is required to be less than the gravity G of the LED chip. In this way, the LED chip will gradually sink, and move in an arc path in the insulating liquid. Since the first substrate is in a static state currently, the initial velocity of the LED chip entering the insulating liquid is 0. In a vertical direction, a falling distance of the LED chip can be expressed as: h=1/2*(G-F_{buoyancy})/m*t; in a horizontal direction, a distance between the two substrates can be expressed as: d=1/2*(E*q−f)/m*t, where t is the time in which the LED chip moves in the insulating liquid. Accordingly, h=d(G−F)/(E*q−f). Therefore, the falling distance h of the LED chip can be determined according to the distance d between the two substrates, the electric field E, and the amount of charges of the LED chip q. To this end, the LED chip can be controlled to reach the predetermined position of the second substrate by adjusting the distance d between the two substrates, the electric field E, and the amount of charges of the LED chip q.

At block S104, whether each opening on the second substrate is filled is determined.

Whether each opening on the second substrate has been filled with an LED chip is determined. If not all the openings are filled with the LED chip, proceed to operations at block S105, that is, a distance between the two substrates is adjusted. If all the openings are filled with the LED chip, the second substrate is taken out of the transfer container and another second substrate is placed in the transfer container, to perform a new round of mass transfer.

At block S105, a distance between the two substrates is adjusted.

The distance between the first substrate and the second substrate is adjusted to a preset value. In the implementation, a desired falling distance h of LED chips to-be-transferred in the next turn can be adjusted by adjusting the distance d between the two substrates, so that the LED chips to-be-transferred in the next turn can reach other openings on the second substrate. Operations at block S102 are performed again to move the LED chips to-be-transferred in the next turn to a predetermined position. The foregoing operations are repeatedly performed until each opening on the second substrate is filled with the LED chip.

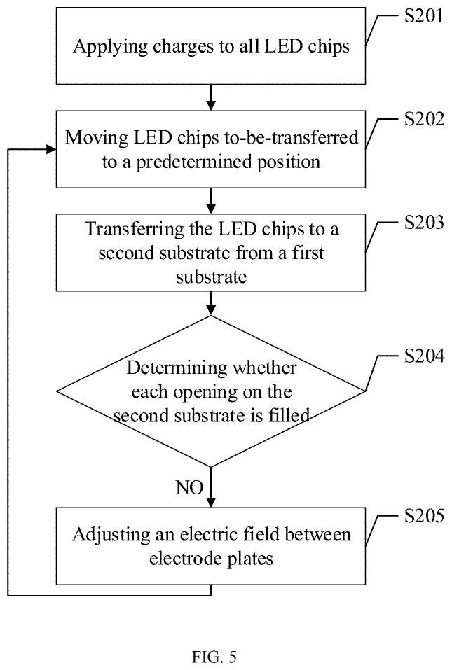

A mass transfer method of the disclosure will be described in detail below with reference to other implementations. As illustrated in FIG. 5, the mass transfer method includes the following.

At block S201, apply charges to all LED chips.

The surfaces of all the LED chips on a first substrate are positively or negatively charged by frictional charging, induction charging, contact charging, or other methods, and the amount of charges is q. In the implementation, the surface of the LED chip is positively charged. Two electrode plates in a transfer container are energized to form a directional electric field E between the two electrode plates. In the implementation, the electrode plate on the left is a positive electrode, and the electrode plate on the right is a negative electrode. Therefore, the electric field is in a rightward direction.

At block 5202, LED chips to-be-transferred are moved to a predetermined position.

After applying the charges, the first substrate is moved to a predetermined position between the two electrode plates. In some implementations, after applying the charges, the first substrate is moved to a position between the two electrode plates. The LED chips to-be-transferred are immersed in the insulating liquid, where a center of gravity of the LED chip and the liquid surface of the insulating liquid are on a same horizontal plane. When the LED chips are moved to the predetermined position, stop moving the first substrate. Since the movement of the first substrate stops, an initial velocity of the LED chip entering the insulating liquid is 0, which is convenient for calculating a falling distance h.

In some implementations, the movement of the first substrate does not stop. In this case, it is necessary to obtain the initial velocity V₀ of the LED chip entering the insulating liquid when calculating the falling distance h.

At block S203, the LED chips are transferred to a second substrate from the first substrate.

The LED chips to-be-transferred are detached from the first substrate by laser irradiation. The LED chips moves directionally in the insulating liquid in the transfer container to a predetermined position of the second substrate under action of the electric field. After entering the insulating liquid, because charges are applied to the surface of the LED chip, under action of the electric field E, the LED chip is subjected to a force in a same direction as the electric field, where the force is required to be greater than the resistance f of the insulating liquid to the LED chip, and the buoyancy F of the selected insulating liquid to the LED chip is required to be less than the gravity G of the LED chip. In this way, the LED chip will gradually sink, and move in an arc path in the insulating liquid. Since the first substrate is in a static state currently, the initial velocity of the LED chip entering the insulating liquid is 0. In a vertical direction, a falling distance of the LED chip can be expressed as: h=1/2*(G−F_{buoyancy})/m*t; in a horizontal direction, a distance between the two substrates can be expressed as: d=1/2*E*q−f)/m*t, where t is the time in which the LED chip moves in the insulating liquid. Accordingly, h=d(G−F)/(E*q−f). Therefore, the falling distance h of the LED chip can be determined according to the distance d between the two substrates, the electric field E, and amount of charges of the LED chip q. To this end, the LED chip can be controlled to reach the predetermined position of the second substrate by adjusting the distance d between the two substrates, the electric field E, and the amount of charges of the LED chip q.

At block S204, whether each opening on the second substrate is filled is determined.

Whether each opening on the second substrate has been filled with an LED chip is determined. If not all the openings are filled with the LED chip, proceed to operations at block S205, that is, an electric field between the electrode plates is adjusted. If all the openings are filled with the LED chip, the second substrate is taken out of the transfer container and another second substrate is placed in the transfer container, to perform a new round of mass transfer.

At block S205, an electric field between the electrode plates is adjusted.

The electric field between the two electrode plates is adjusted to a preset value. In the implementation, a desired falling distance h of LED chip to-be-transferred in the next round can be adjusted by adjusting the electric field E of the two electrode plates, so that the LED chips to-be-transferred in the next turn can reach other openings on the second substrate. Operations at block S202 are performed again to move the LED chips to-be-transferred in the next turn to a predetermined position. The foregoing operations are repeatedly performed until each opening on the second substrate is filled with the LED chip.

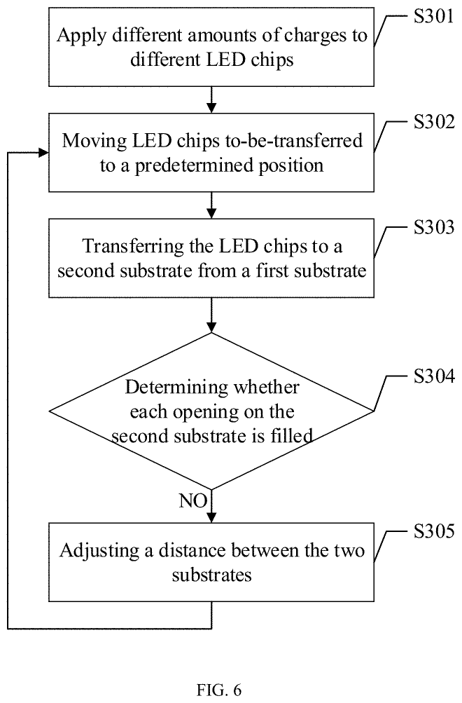

A mass transfer method of the disclosure will be described in detail below with reference to other implementations. As illustrated in FIG. 6, the mass transfer method includes the following.

At block S301, apply different amounts of charges to different LED chips.

The amounts of charges on the surfaces of LED chips of different transfer batches on the first substrate may be the same or different by friction charging, induction charging, contact charging, or other methods, and the amounts of charges are q₁, q₂, and q₃ respectively. In the implementation, LED chips of a same transfer batch are at the same level, and the surfaces of the LED chips are all positively charged. Two electrode plates in a transfer container are energized to form a directional electric field E between the two electrode plates. In the implementation, the electrode plate on the left is a positive electrode, and the electrode plate on the right is a negative electrode. Therefore, the electric field is in a rightward direction. In some implementations of the disclosure, only one type of LED chips can be transferred. In some implementations of the disclosure, LED chips of three colors (e.g., red LED chips, green LED chips, and blue LED chips) can be transferred at the same time. The LED chips of three colors are respectively arranged on three different first substrates, and LED chips of each color may carry different amounts of charges.

At block S302, LED chips to-be-transferred are moved to a predetermined position.

After applying the charges, the first substrate is moved to a predetermined position between the two electrode plates. In some implementations, after applying the charges, the first substrate is moved to a position between the two electrode plates. The LED chips to-be-transferred are immersed in insulating liquid, where a center of gravity of the LED chip and the liquid surface of the insulating liquid are on a same horizontal plane. When the LED chips are moved to the predetermined position, stop moving the first substrate. Since the movement of the first substrate stops, an initial velocity of the LED chip entering the insulating liquid is 0, which is convenient for calculating a falling distance h of the LED chip.

In some implementations, the movement of the first substrate does not stop. In this case, it is necessary to obtain the initial velocity V₀ of the LED chip entering the insulating liquid when calculating the falling distance h.

When LED chips on three first substrates are transferred at the same time, after applying charges to the LED chips on the three first substrates, the three first substrates are respectively moved to positions at different distances from the second substrate.

At block S303, the LED chips are transferred to a second substrate from the first substrate.

The LED chips to-be-transferred are detached from the first substrate by laser irradiation. The LED chips move directionally in the insulating liquid in the transfer container to a predetermined position of the second substrate under action of the electric field. After entering the insulating liquid, because charges are applied to the surface of the LED chip, under action of the electric field E, the LED chip is subjected to a force in a same direction as the electric field, where the force is required to be greater than the resistance f of the insulating liquid to the LED chip, and the buoyancy F of the selected insulating liquid to the LED chip is required to be less than the gravity G of the LED chip. In this way, the LED chip will gradually sink, and move in an arc path in the insulating liquid. Since the first substrate is in a static state currently, the initial velocity of the LED chip entering the insulating liquid is 0. In a vertical direction, a falling distance of the LED chip can be expressed as: h=1/2*(G−F_{buoyancy})/m*t; in a horizontal direction, a distance between the two electrode plates can be expressed as: d=1/2*(E*q−f)/m*t, where t is the time in which the LED chip moves in the insulating liquid. Accordingly, h=d(G−F)/(E*q−f). Therefore, the falling distance h of the LED chip can be determined according to the distance d between the two electrode plates, the electric field E, and the amount of charges of the LED chip q. To this end, the LED can be controlled to reach the predetermined position of the second substrate by adjusting the distance d between the two substrates, the electric field E, and the amount of charges of the LED chip q.

At block S304, whether each opening on the second substrate is filled is determined.

Whether each opening on the second substrate has been filled with an LED chip is determined. If not all the openings are filled with the LED chip, proceed to operations at block S305, that is, a distance between the two substrates is adjusted. If all the openings are filled with the LED chip, the second substrate is taken out of the transfer container and another second substrate is placed in the transfer container, to perform a new round of mass transfer.

At block 5305, a distance between the two substrates is adjusted.

A distance between each of the three first substrates and the second substrate is adjusted to a preset value. In the implementation, a desired falling distance h of LED chips to-be-transferred in the next turn can be adjusted by adjusting the distance d between the two substrates, so that the LED chips to-be-transferred in the next turn can reach other openings on the second substrate. Operations at block 5302 are performed again to move the LED chips to-be-transferred in the next turn to a predetermined position. The foregoing operations are repeatedly performed until each opening on the second substrate is filled with the LED chip.

In the description of the specification of the disclosure, the description with reference to the terms “one implementation”, “some implementations”, “illustrative implementations”, “examples”, “illustrative examples”, or “some examples”, and the like means that a specific feature, structure, material, or characteristic described in combination with an implementation or an example is included in at least one implementation or example of the disclosure. In the specification, the schematic representation of the above-mentioned terms does not necessarily refer to a same implementation or example. Moreover, the described specific feature, structure, material, or characteristic can be combined in an appropriate manner in any one or more implementations or examples.

While the disclosure has been described in connection with some illustrative implementations, which however are not intended to limit the disclosure. Any modifications, equivalent substitutions, or improvements made by those skilled in the art without departing from the spirits and principles of the disclosure shall all be encompassed within the protection scope of the disclosure.

What is claimed is:

1. A mass transfer device, comprising:
a transfer container, filled with insulating liquid and provided with two electrode plates, the two electrode plates being arranged opposite to each other and having opposite electrical polarities; one of the two electrode plates being vertically provided with a second substrate on a surface of the electrode plate opposite to the other one of the two electrode plates, the second substrate being configured to hold transferred light-emitting diode (LED) chips; the transfer container being externally provided with a laser emitter, the laser emitter being aligned with LED chips on a first substrate, the first substrate being vertically arranged between the two electrode plates; the first substrate being mounted on a first displacement device, the first displacement device being configured to control the first substrate to move vertically downward at a preset speed.

2. The mass transfer device of claim 1, wherein the second substrate is mounted on a second displacement device, and the second displacement device is configured to control the second substrate to move vertically upward at a preset speed.

3. The mass transfer device of claim 1, wherein the laser emitter is arranged above the liquid surface of the insulating liquid.

4. The mass transfer device of claim 1, wherein the laser emitter is embodied as three laser emitters, and the number of the laser emitters is consistent with that of the first substrates.

5. The mass transfer device of claim 4, wherein each of the laser emitters is mounted on a mounting position of a laser-emitter fixing frame, and adjacent mounting positions are separated by a space for placing the first substrate.

6. The mass transfer device of claim 5, wherein the laser-emitter fixing frame is provided with a regulator, and the regulator is configured to adjust a distance between two adjacent mounting positions.

7. The mass transfer device of claim 4, wherein the second substrate has openings for holding transferred LED chips, and the number of the openings is greater than three.

8. The mass transfer device of claim 7, wherein each of the openings is coated with an adhesive layer.

9. The mass transfer device of claim 4, wherein three first substrates are provided with red LED chips, green LED chips, and blue LED chips respectively.

10. The mass transfer device of claim 1, further comprising:
a charge generator, configured to apply charges to LED chips on the first substrates.

11. The mass transfer device of claim 1, further comprising a power controller connected with the two electrode plates, wherein the power controller is configured to adjust an electric field intensity between the two electrode plates.

12. The mass transfer device of claim 1, wherein the first substrate is provided with a distance control component, and the distance control component is configured to adjust a distance between the first substrate and the second substrate.

13. The mass transfer device of claim 1, wherein the insulating liquid is insulating oil.

14. A mass transfer method, comprising:
applying charges to all LED chips on a first substrate, and energizing two electrode plates in a transfer container to form a directional electric field between the two electrode plates, the first substrate being vertically arranged between the two electrode plates, the two electrode plates being arranged opposite to each other and having opposite electrical polarities, one of the two electrode plates being vertically provided with a second substrate on a surface of the electrode plate opposite to the other one of the two electrode plates;
moving the first substrate to a predetermined position between the two electrode plates, after applying the charges; and
performing laser irradiation to make LED chips to-be-transferred be detached from the first substrate and move directionally in insulating liquid in the transfer container to a predetermined position of the second substrate under action of the electric field.

15. The mass transfer method of claim 14, wherein moving the first substrate to the predetermined position between the two electrode plates after applying the charges comprises:
moving the first substrate to a position between the two electrode plates after applying the charges, and immersing the LED chips to-be-transferred in the insulating liquid, wherein a center of gravity of the LED chip and the liquid surface of the insulating liquid are on a same horizontal plane.

16. The mass transfer method of claim 14, wherein the first substrate is embodied as three first substrates, and moving the first substrate to the predetermined position between the two electrode plates after applying the charges comprises:
moving the three first substrates to respective predetermined positions between the two electrode plates after applying the charges.

17. The mass transfer method of claim 14, further comprising:
stopping moving the first substrate, after moving the first substrate to the predetermined position between the two electrode plates after applying the charges.

18. The mass transfer method of claim 14, further comprising:
after moving directionally in the insulating liquid in the transfer container to the predetermined position of the second substrate under action of the electric field,
adjusting the distance between the first substrate and the second substrate to a preset value, and moving the first substrate to a predetermined position between the two electrode plates at a preset speed.

19. The mass transfer method of claim 14, further comprising:
after moving directionally in the insulating liquid in the transfer container to the predetermined position of the second substrate under action of the electric field,
adjusting the electric field between the two electrode plates to a preset value, and moving the first substrate to a predetermined position between the two electrode plates at a preset speed.

20. The mass transfer method of claim 14, wherein applying charges to all LED chips on the first substrate comprises:
applying different amounts of charges to different LED chips on the first substrates.
